(19) United States
(12) Patent Application Publication
(10) Pub. No.: US 2025/0324833 A1
(43) Pub. Date: Oct. 16, 2025

(54) DISPLAY DEVICE

(71) Applicant: Samsung Display Co., LTD., Yongin-si (KR)

(72) Inventor: Do Yeong PARK, Yongin-si (KR)

(73) Assignee: Samsung Display Co., LTD., Yongin-si (KR)

(21) Appl. No.: 19/013,116

(22) Filed: Jan. 8, 2025

(30) Foreign Application Priority Data
Apr. 11, 2024 (KR) 10-2024-0048480

(51) Int. Cl. H10H 29/37

(52) U.S. Cl. CPC H10H 29/37

(57) ABSTRACT

A display device includes a pixel electrode disposed on a substrate, a first bank layer covering an edge of the pixel electrode and including a stem portion extending in a first direction and a protrusion portion protruded from the stem portion in a second direction, and a second bank layer disposed on the edge of the pixel electrode and a portion of the first bank layer and including a stem portion extending in the second direction and a first protrusion portion protruded from the stem portion in the first direction. The stem portions of the first bank layer and the second bank layer include a cross portion where they cross each other, the protrusion portion of the first bank layer is adjacent to the crossing portion of the stem portion, and the first protrusion portion is adjacent to the crossing portion of the stem portion.

### CROSS-REFERENCE TO RELATED APPLICATION(S)

This application claims priority to and benefits of Korean Patent Application No. 10-2024-0048480 under 35 U.S.C. 119, filed on Apr. 11, 2024, in the Korean Intellectual Property Office (KIPO), the entire contents of which are incorporated herein by reference.

### BACKGROUND

### 1. Technical Field

The disclosure relates to a display device.

### 2. Description of the Related Art

With the advancement of the information age, the demand for a display device for displaying an image has increased with various forms. For example, the display device has been applied to various electronic devices such as a smart phone, a digital camera, a laptop computer, a navigator, and a smart television.

The display device may be a flat panel display device such as a liquid crystal display device, a field emission display device, and a light emitting display device. The light emitting display device may include an organic light emitting display device including an organic light emitting element or an inorganic light emitting display device including an inorganic light emitting element such as a quantum-dot.

### SUMMARY

An object of the disclosure is to provide a display device that may reduce diffusion of a colure mixture.

According to an embodiment, a display device may include a pixel electrode disposed on a substrate, a first bank layer covering an edge of the pixel electrode and including a stem portion extending in a first direction and a protrusion portion protruded from the stem portion in a second direction intersecting the first direction, and a second bank layer disposed on the edge of the pixel electrode and a portion of the first bank layer and including a stem portion extending in the second direction and a first protrusion portion protruded from the stem portion in the first direction. The stem portion of the first bank layer and the stem portion of the second bank layer may include a cross portion where the stem portion of the first bank layer and the stem portion of the second bank layer cross each other, the protrusion portion of the first bank layer may be adjacent to the crossing portion of the stem portion of the first bank layer, and the first protrusion portion of the second bank layer may be adjacent to the crossing portion of the stem portion of the second bank layer.

At least a portion of the protrusion portion of the first bank layer and at least a portion of the first protrusion portion of the second bank layer may overlap the pixel electrode in a thickness direction of the substrate.

At least a portion of the protrusion portion of the first bank layer may be exposed without being covered by the second bank layer.

The first protrusion of the second bank layer may include a first area adjacent to the stem portion of the second bank layer and a second area farther from the stem portion of the second bank layer in the first direction than the first area, and a length of the first area in the second direction may be smaller than a length of the second area in the second direction.

The first protrusion portion of the second bank layer may include a third area disposed between the first area and the second area, and a length of the third area in the second direction may be greater than a length of the first area in the second direction.

The length of the third area in the second direction may be smaller than the length of the second area in the second direction.

The first protrusion portion of the second bank layer may include an eleventh area adjacent to the stem portion of the first bank layer and a twelfth area farther from the stem portion of the first bank layer in the second direction than the eleventh area, and a length of the eleventh area in the first direction may be greater than a length of the twelfth area in the first direction.

The first protrusion portion of the second bank layer may overlap the first bank layer in a thickness direction of the substrate.

The second bank layer may further include a second protrusion portion protruded from the stem portion in the first direction and not overlapping the first bank layer in the thickness direction.

The second protrusion portion may overlap an entire area of the pixel electrode in the thickness direction.

A thickness of the second bank layer may be greater than a thickness of the first bank layer.

The display device may further include a light emitting structure disposed on the pixel electrode and the first bank layer.

The light emitting structure may extend in the second direction.

The first bank layer may include a lyophilic material, and the second bank layer may include a liquid repellent material.

According to an embodiment of the disclosure, a display device may include a pixel electrode disposed on a substrate, a first bank layer covering an edge of the pixel electrode and extending in a first direction, a second bank layer disposed on the edge of the pixel electrode and a portion of the first bank layer and including a stem portion extending in a second direction intersecting the first direction and a first protrusion portion protruded from the stem portion in the first direction, and a light emitting structure disposed on the pixel electrode. The first protrusion portion of the second bank layer may include a first area adjacent to the stem portion of the second bank layer and a second area farther from the stem portion of the second bank layer in the first direction than the first area, a length of the first area in the second direction may be smaller than a length of the second area in the second direction, and a portion of the light emitting structure may be disposed between the stem portion of the second bank layer and the first protrusion portion of the second bank layer.

The light emitting structure disposed between the stem portion of the second bank layer and the first protrusion portion of the second bank layer may include a 21st area adjacent to the first bank layer and a 22nd area farther from the first bank layer in the second direction than the 21st area, and a length of the 21st area in the first direction may be smaller than a length of the 22nd area in the first direction.

The first bank layer may include a stem portion extending in the first direction and a protrusion portion protruded from the stem portion in the second direction, and the protrusion portion of the first bank layer may be disposed between the stem portion of the second bank layer and the first protrusion portion of the second bank layer.

The first protrusion portion of the second bank layer may include a third area disposed between the first area and the second area, and a length of the third area in the second direction may be greater than a length of the first area in the second direction, and may be smaller than a length of the second area in the second direction.

The first protrusion portion of the second bank layer may have a reverse tapered shape or a stepped shape in a plan view.

The second bank layer may further include a second protrusion portion protruded from the stem portion in the first direction and not overlapping the first bank layer in a thickness direction of the substrate.

The objects of the disclosure are not limited to those mentioned above and additional objects of the disclosure, which are not mentioned herein, will be clearly understood by those skilled in the art from the following description of the disclosure.

The display device according to an embodiment may include a bank including a protrusion to prevent overflowing ink from being diffused, thereby reducing a color mixture or a spot of a display panel.

The effects according to the embodiments of the disclosure are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating a display device according to an embodiment;

FIG. 2 is a plan view illustrating a display device according to an embodiment;

FIG. 3 is a schematic cross-sectional view taken along line Q1-Q1′ of FIG. 2;

FIG. 4 is a plan view illustrating an arrangement of a light emission area and a non-light emission area of a display device according to an embodiment;

FIG. 5 is a schematic cross-sectional view taken along line Q2-Q2′ of FIG. 4;

FIG. 6 is a schematic cross-sectional view taken along line Q3-Q3′ of FIG. 4;

FIG. 7 is an enlarged schematic cross-sectional view illustrating a first light emission area of a display device shown in FIG. 5;

FIG. 8 is an enlarged plan view illustrating area A2 of FIG. 4;

FIG. 9 is an enlarged plan view illustrating a display device according to an embodiment;

FIG. 10 is an enlarged plan view illustrating a display device according to an embodiment;

FIG. 11 is a plan view illustrating an arrangement of a light emission area and a non-light emission area of a display device according to an embodiment;

FIG. 12 is an enlarged plan view illustrating area A3 of FIG. 11; and

FIG. 13 is an enlarged plan view illustrating a display device according to an embodiment.

### DETAILED DESCRIPTION OF THE EMBODIMENTS

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure thorough and for fully conveying the scope of the disclosure to those skilled in the art. It is to be noted that the scope of the disclosure is defined only by the claims.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. Like reference numerals denote like elements throughout the descriptions.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Features of various embodiments of the disclosure may be combined partially or totally. As will be clearly appreciated by those skilled in the art, technically various interactions and operations are possible. Various embodiments can be practiced individually or in combination.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the accompanying drawings.

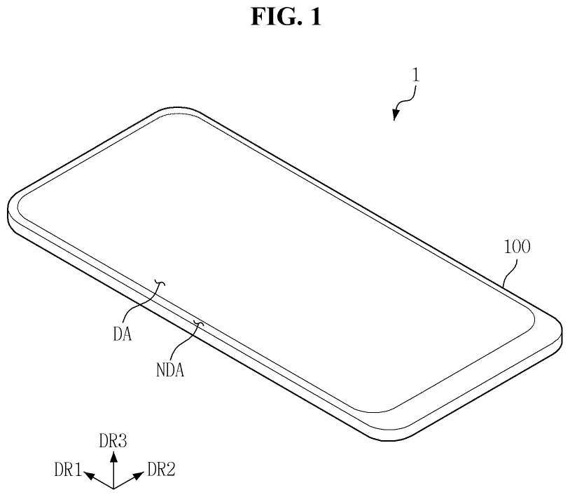

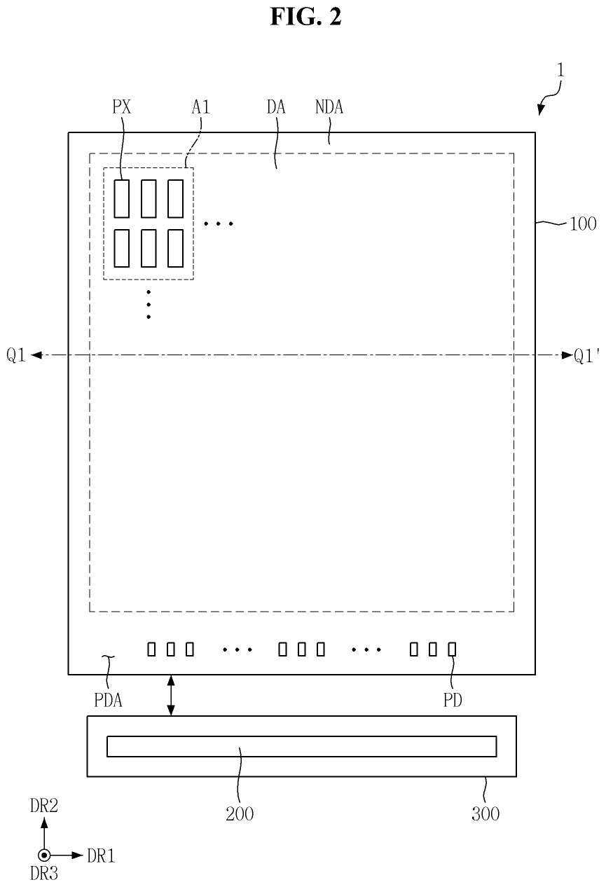

FIG. 1 is a perspective view illustrating a display device according to an embodiment. FIG. 2 is a plan view illustrating a display device according to an embodiment.

Referring to FIG. 1, a display device 1 may display a moving image or a still image. The display device 1 may be any electronic device that provides a display screen. For example, a television, a laptop computer, a monitor, an advertising board, Internet of Things, a mobile phone, a smart phone, a tablet personal computer (PC), an electronic watch, smart glasses, a smart watch, a watch phone, a head mounted display, a mobile communication terminal, an electronic diary, an electronic book, a portable multimedia player (PMP), a navigator, a game machine, a digital camera, a camcorder and the like, which provide a display screen, may include the display device 1.

Examples of the display device 1 may include an inorganic light emitting diode display device, an organic light emitting display device, a quantum dot light emitting display device, a plasma display device and a field emission display device. The following description will be based on an embodiment that the display device is an inorganic light emitting diode display device, but the disclosure is not limited thereto and the display device 1 may be applicable to another display device within the range that the same technical spirits are applicable thereto.

Various modifications may be made in a shape of the display device 1. For example, the display device 1 may have a shape such as a rectangle of a long width, a rectangle of a long length, a square, a rectangle of round corners (vertexes), other polygons and a circle in a plan view. A shape of a display area DA of the display device 1 may be similar to an overall shape of the display device 1. A rectangular display device 1 having a long length in a first direction DR1 is illustrated in FIG. 1, but the disclosure is not limited thereto.

Referring to FIGS. 1 and 2, the display device 1 may include a display panel 100, a display driver 200 and a circuit board 300.

The display panel 100 may have a rectangular shape having a long side in the first direction DR1 and a short side in a second direction DR2 intersecting the first direction DR1 in a plan view. A corner where the long side in the first direction DR1 and the short side in the second direction DR2 meet may be rounded to have a curvature or formed at a right angle. However, the shape of the display panel 100 is not limited to a rectangular shape, and may be formed in another polygonal shape, a circular shape or an oval shape. The display panel 100 may be formed to be flat, but the disclosure is not limited thereto. The display panel 100 may include a curved portion formed at left and right ends, having a constant curvature or a variable curvature. In an embodiment, the display panel 100 may be flexibly formed to be curved, bendable, foldable, or rollable.

The display panel 100 may include a display area DA, a non-display area NDA and a pad area PDA.

The display area DA may generally occupy the center of the display device 1. Multiple pixels PX may be disposed in the display area DA. Each of the pixels PX may be defined as a minimum unit for emitting light. The pixels PX may be connected to signal lines positioned in the non-display area NDA. The display area DA may emit light from a light emission area included in the pixels PX or multiple openings.

The non-display area NDA may be an area outside the display area DA. The non-display area NDA may be an area adjacent to an edge of the display panel 100, and may be an area surrounding the display area DA in a plan view. The non-display area NDA may include a gate driver (not shown) supplying gate signals to gate lines, and a fan-out line (not shown) connecting the display driver 200 to the display area DA.

The display driver 200 may output signals and voltages for driving the display panel 100. In detail, the display driver 200 may output signals and voltages for driving the pixels PX disposed in the display area DA. The display driver 200 may supply data voltages to data lines of the display panel 100. The display driver 200 may supply a power voltage to a power line, and may supply a gate control signal to a gate driver of the display panel 100.

The circuit board 300 may be attached onto a pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip-on-film.

The display driver 200 may be formed of an integrated circuit (IC), and may be packaged on the circuit board 300 by a Chip on Glass (COG) method, a Chip on Plastic (COP) method or an ultrasonic bonding method.

Multiple display pads PD may be disposed in the pad area PDA of the display panel 100. The display pads PD may be disposed on an edge of the pad area PDA. The display pads PD may be connected to a graphic system through the circuit board 300. The display pads PD may be connected to the circuit board 300 to receive digital video data, and may supply the digital video data to the display driver 200.

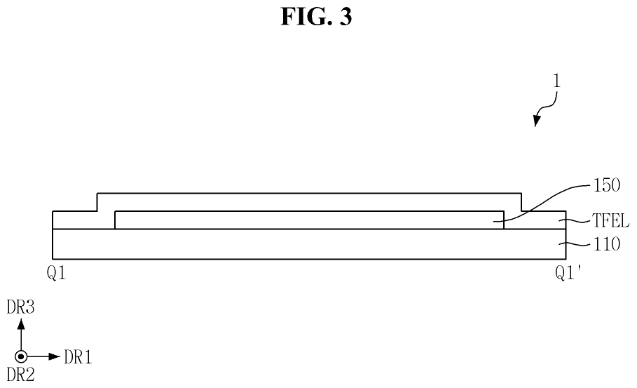

FIG. 3 is a schematic cross-sectional view taken along line Q1-Q1′ of FIG. 2.

Referring to FIG. 3, the display device 1 may include a substrate 110, a light emitting element layer 150, and a thin film encapsulation layer TFEL.

The substrate 110 may be a base substrate or a base member. The substrate 110 may be a flexible substrate capable of being subjected to bending, folding, rolling and the like. For example, the substrate 110 may include a polymer resin including polyimide (PI), but the disclosure is not limited thereto. In another embodiment, the substrate 110 may include a glass material or a metal material.

The light emitting element layer 150 may include a pixel circuit including switching elements, a pixel defining layer defining a light emission area or an opening area, and a self-light emitting element. For example, the self-emitting element may include at least one of an organic light emitting diode including an organic light emitting layer, a quantum dot LED including a quantum dot light emitting layer, an inorganic light emitting diode (inorganic LED) including an inorganic semiconductor, and a micro light emitting diode (micro LED), but the disclosure is not limited thereto.

The thin film encapsulation layer TFEL may prevent impurities such as external moisture or air from being permeated and diffused into the light emitting element layer 150. The thin film encapsulation layer TEFL may have a structure in which multiple inorganic layers and multiple organic layers are stacked each other.

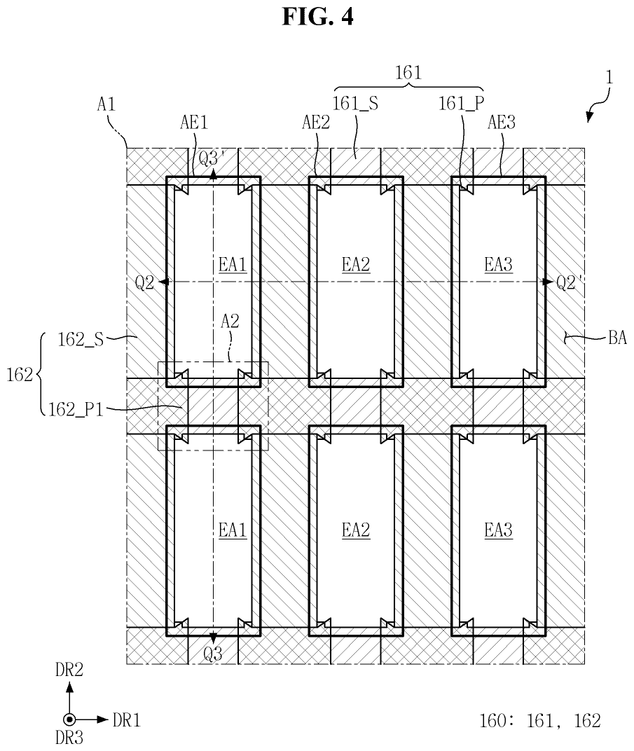

FIG. 4 is an enlarged plan view illustrating an arrangement of light emission areas EA1, EA2 and EA3 and a non-light emission area BA of the display device according to an embodiment, and is an enlarged view of an area A1 of FIG. 2.

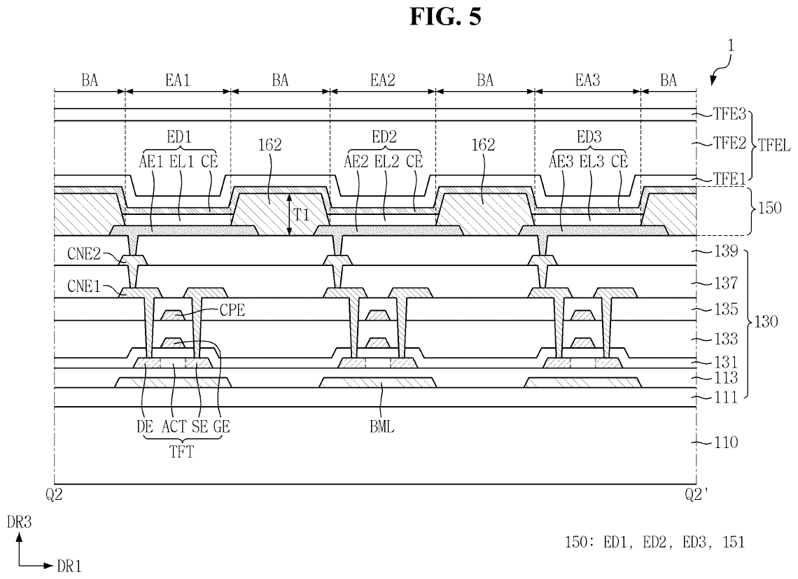

Referring to FIG. 4, the display device 1 may include multiple light emission areas EA1, EA2 and EA3 disposed in the display area DA. The light emission areas EA1, EA2 and EA3 may be areas that are not covered by a bank layer 160 or areas where pixel electrodes AE1, AE2 and AE3 of light emitting elements (ED1, ED2 and ED3 of FIG. 5), light emitting structures EL1, EL2 and EL3 and a common electrode CE overlap one another in a plan view.

The light emission areas EA1, EA2 and EA3 may include a first light emission area EA1, a second light emission area EA2, and a third light emission area EA3, which emit light of different colors. The light emission areas EA1, EA2 and EA3 may emit red, green or blue light, respectively, and colors of the light emitted from the light emission areas EA1, EA2 and EA3 may be different depending on types of the light emitting elements (ED1, ED2 and ED3 of FIG. 5) disposed in the light emitting element layer (150 of FIG. 5) of each of the light emission areas EA1, EA2 and EA3. In an embodiment, the first light emission areas EA1 may emit red light or first light, the second light emission areas EA2 may emit green light or second light, and the third light emission areas EA3 may emit blue light or third light.

The non-light emission area BA may be an area surrounding each of the light emission areas EA1, EA2 and EA3 in a plan view, and the non-light emission area BA may be an area through which light does not pass. The non-light emission area BA may be an area in which the bank layer 160 is disposed. The bank layer 160 may include a first bank layer 161 and a second bank layer 162 disposed on the first bank layer 161.

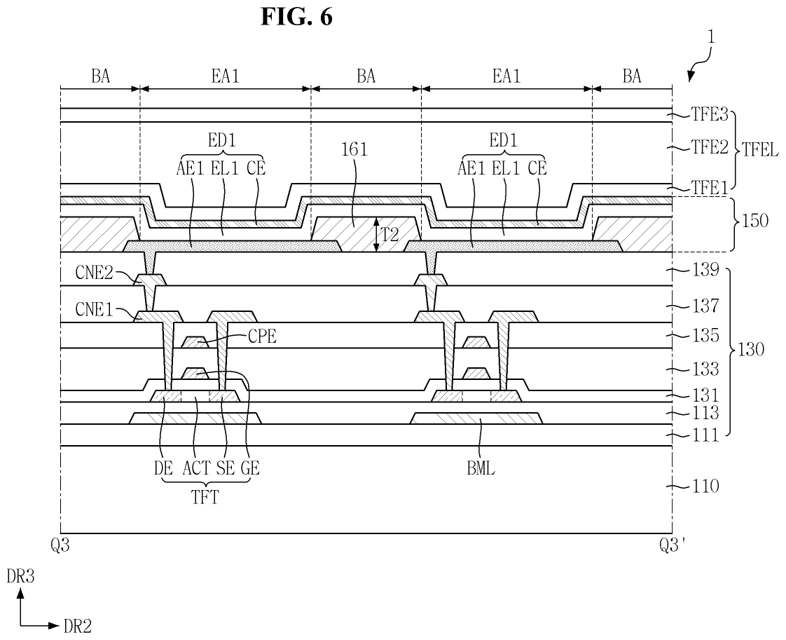

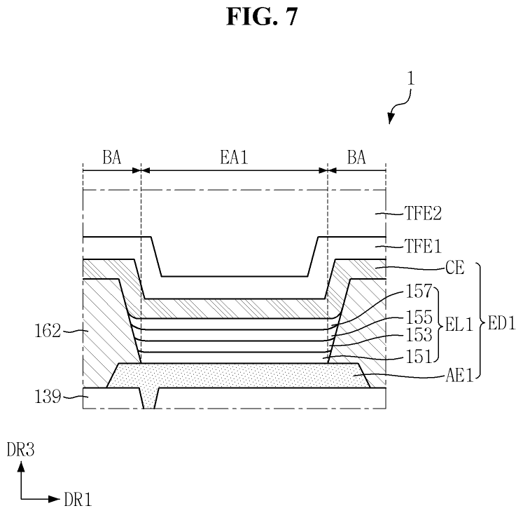

FIG. 5 is a schematic cross-sectional view taken along line Q2-Q2′ of FIG. 4, and FIG. 6 is a schematic cross-sectional view taken along line Q3-Q3′ of FIG. 4. FIG. 7 is an enlarged schematic cross-sectional view illustrating a first light emission area of a display device shown in FIG. 5.

Referring to FIG. 5, the display device 1 may include a substrate 110, a thin film transistor layer 130, a light emitting element layer 150, and a thin film encapsulation layer TFEL.

The thin film transistor layer 130 may be disposed on the substrate 110. The thin film transistor layer 130 may include a first buffer layer 111, a lower metal layer BML, a second buffer layer 113, a thin film transistor TFT, a gate insulating layer 131, a first interlayer insulating layer 133, a capacitor electrode CPE, a second interlayer insulating layer 135, a first connection electrode CNE1, a first passivation layer 137, a second connection electrode CNE2, and a second passivation layer 139.

The first buffer layer 111 may be disposed on the substrate 110. The first buffer layer 111 may include an inorganic layer capable of preventing permeation of the air or moisture. For example, the first buffer layer 111 may include multiple inorganic layers that are alternately stacked with each other.

The lower metal layer BML may be disposed on the first buffer layer 111. For example, the lower metal layer BML may be formed of a single layer or multi-layer made including at least one of molybdenum (Mo), aluminum (Al), chromium (Cr), gold (Au), titanium (Ti), nickel (Ni), neodymium (Nd) and copper (Cu), and an alloy thereof.

The second buffer layer 113 may cover the first buffer layer 111 and the lower metal layer BML. The second buffer layer 113 may include an inorganic layer capable of preventing permeation of the air or moisture. For example, the second buffer layer 113 may include multiple inorganic layers that are alternately stacked with each other.

The thin film transistor TFT may be disposed on the second buffer layer 113, and may constitute a pixel circuit of each of the pixels. The thin film transistor TFT may be a driving transistor or a switching transistor of the pixel circuit. The thin film transistor TFT may include a semiconductor layer ACT, a source electrode SE, a drain electrode DE, and a gate electrode GE. The thin film transistor TFT may be a low-temperature polysilicon thin film transistor (LTPS) or an oxide thin film transistor.

The semiconductor layer ACT may be disposed on the second buffer layer 113. The semiconductor layer ACT may overlap the lower metal layer BML and the gate electrode GE in a thickness direction, and may be insulated from the gate electrode GE by the gate insulating layer 131. A portion of the semiconductor layer ACT may be formed by conductorizing a material of the semiconductor layer ACT to form the source electrode SE and the drain electrode DE.

The gate electrode GE may be disposed on the gate insulating layer 131. The gate electrode GE may overlap the semiconductor layer ACT in a plan view with the gate insulating layer 131 interposed between the gate electrode GE and the semiconductor layer ACT.

The gate insulating layer 131 may be disposed on the semiconductor layer ACT. For example, the gate insulating layer 131 may cover the semiconductor layer ACT and the second buffer layer 113, and may insulate the semiconductor layer ACT from the gate electrode GE. The gate insulating layer 131 may include a contact hole through which a first connection electrode CNE1 passes.

The first interlayer insulating layer 133 may cover the gate electrode GE and the gate insulating layer 131. The first interlayer insulating layer 133 may include a contact hole through which the first connection electrode CNE1 passes. The contact hole of the first interlayer insulating layer 133 may be connected to the contact hole of the gate insulating layer 131 and a contact hole of the second interlayer insulating layer 135.

The capacitor electrode CPE may be disposed on the first interlayer insulating layer 133. The capacitor electrode CPE may overlap the gate electrode GE in the thickness direction. The capacitor electrode CPE and the gate electrode GE may form a capacitor.

The second interlayer insulating layer 135 may cover the capacitor electrode CPE and the first interlayer insulating layer 133. The second interlayer insulating layer 135 may include a contact hole through which the first connection electrode CNE1 passes. The contact hole of the second interlayer insulating layer 135 may be connected to the contact hole of the first interlayer insulating layer 133 and the contact hole of the gate insulating layer 131.

The first connection electrode CNE1 may be disposed on the second interlayer insulating layer 135. The first connection electrode CNE1 may electrically connect the drain electrode DE of the thin film transistor TFT to the second connection electrode CNE2. The first connection electrode CNE1 may be in contact with the drain electrode DE of the thin film transistor TFT through the contact holes formed in the second interlayer insulating layer 135, the first interlayer insulating layer 133, and the gate insulating layer 131.

The first passivation layer 137 may cover the first connection electrode CNE1 and the second interlayer insulating layer 135. The first passivation layer 137 may protect the thin film transistor TFT. The first passivation layer 137 may include a contact hole through which the second connection electrode CNE2 passes.

The second connection electrode CNE2 may be disposed on the first passivation layer 137. The second connection electrode CNE2 may electrically connect the first connection electrode CNE1 to the pixel electrodes AE1, AE2 and AE3 of the light emitting elements ED1, ED2 and ED3. The second connection electrode CNE2 may be in contact with the first connection electrode CNE1 through the contact hole formed in the first passivation layer 137.

The second passivation layer 139 may cover the second connection electrode CNE2 and the first passivation layer 137. The second passivation layer 139 may include a contact hole through which the pixel electrodes AE1, AE2 and AE3 of the light emitting elements ED1, ED2 and ED3 pass.

The light emitting element layer 150 may be disposed on the thin film transistor layer 130. The light emitting element layer 150 may include bank layers 161 and 162 defining the light emission areas EA1, EA2 and EA3, and multiple light emitting elements ED1, ED2 and ED3 respectively disposed in the light emission areas EA1, EA2 and EA3. The light emitting elements ED1, ED2 and ED3 may include pixel electrodes AE1, AE2 and AE3, light emitting structures EL1, EL2 and EL3 and a common electrode CE, respectively.

The light emission areas EA1, EA2 and EA3 may be defined by the bank layer 160. An area exposed without being covered by the bank layer 160 may be the light emission areas EA1, EA2 and EA3.

The light emitting elements ED1, ED2 and ED3 may include a first light emitting element ED1 disposed in the first light emission area EA1, a second light emitting element ED2 disposed in the second light emission area EA2 and a third light emitting element ED3 disposed in the third light emission area EA3. The light emitting elements ED1, ED2 and ED3 may emit light of different colors, such as red, blue, green, or white, depending on the materials of the light emitting structures EL1, EL2 and EL3. For example, the first light emitting element ED1 disposed in the first light emission area EA1 may emit red light of a first color, the second light emitting element ED2 disposed in the second light emission area EA2 may emit green light of a second color, and the third light emitting element ED3 disposed in the third light emission area EA3 may emit blue light of a third color. The three light emission areas EA1, EA2 and EA3 constituting one pixel may include three light emitting elements ED1, ED2 and ED3 that emit light of different colors to express a white gray scale.

Each of the pixel electrodes AE1, AE2 and AE3 may be formed on the second passivation layer 139. The pixel electrodes AE1, AE2 and AE3 may be disposed in areas corresponding to the light emission areas EA1, EA2 and EA3. Each of the pixel electrodes AE1, AE2 and AE3 may be electrically connected to the drain electrode DE of the thin film transistor TFT through the first connection electrode CNE1 and the second connection electrode CNE2. The pixel electrodes AE1, AE2 and AE3 may include a first pixel electrode AE1 disposed in the first light emission area EA1, a second pixel electrode AE2 disposed in the second light emission area EA2 and a third pixel electrode AE3 disposed in the third light emission area EA3. The first pixel electrode AE1, the second pixel electrode AE2 and the third pixel electrode AE3 may be disposed to be spaced apart from one another on the second passivation layer 139.

The pixel electrodes AE1, AE2 and AE3 may include a material, which is transparent and has a high work function, such as indium-tin-oxide (ITO), indium-zinc-oxide (IZO), zinc oxide (ZnO), and indium oxide (In2O3). In case that the pixel electrodes AE1, AE2 and AE3 are reflective electrodes, the pixel electrodes AE1, AE2 and AE3 may have a stacked layer structure in which a material layer having the above-described high work function and a reflective material layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or a mixture thereof are stacked each other. For example, the pixel electrodes AE1, AE2 and AE3 may have a multi-layered structure of ITO/Mg, ITO/MgF, ITO/Ag, or ITO/Ag/ITO, but are not limited thereto.

The light emitting structures EL1, EL2 and EL3 may be respectively disposed on the pixel electrodes AE1, AE2 and AE3. In each of the light emitting structures EL1, EL2 and EL3, the thin film transistor TFT may apply a voltage to the pixel electrodes AE1, AE2 and AE3 of the light emitting elements ED1, ED2 and ED3, and the common electrode CE of the light emitting elements ED1, ED2 and ED3 may receive a common voltage or a cathode voltage, so that light may be emitted from the light emitting structures EL1, EL2 and EL3 of the light emitting elements ED1, ED2 and ED3.

The light emitting structures EL1, EL2 and EL3 may include a first light emitting structure EL1, a second light emitting structure EL2 and a third light emitting structure EL3, which are disposed in different light emission areas EA1, EA2 and EA3. The first light emitting structure EL1 may be disposed on the first pixel electrode AE1 in the first light emission area EA1, the second light emitting structure EL2 may be disposed on the second pixel electrode AE2 in the second light emission area EA2, and the third light emitting structure EL3 may be disposed on the third pixel electrode AE3 in the third light emission area EA3. In an embodiment, the light emitting structures EL1, EL2 and EL3 included in the display device 1 may include a quantum dot.

The first light emission area EA1 according to an embodiment is shown in FIG. 7. The light emitting structures EL1, EL2 and EL3 will be described based on the first light emitting structure EL1 as an example.

The first light emitting structure EL1 may include a hole injection layer 151, a hole transport layer 153, a light emitting layer 155 and an electron transport layer 157.

The hole injection layer 151 may be disposed on the pixel electrodes AE1, AE2 and AE3. The hole injection layer 151 may serve to facilitate hole injection from the pixel electrodes AE1, AE2 and AE3 to the light emitting layer 155.

For example, the hole injection layer 151 may include a phthalocyanine compound such as copper phthalocyanine, DNTPD(N,N′-diphenyl-N,N′-bis-[4-(phenyl-m-tolyl-amino)-phenyl]-biphenyl-4,4′-diamine), m-MTDATA(4,4′,4″-[tris(3-methylphenyl)phenylamino] triphenylamine), TDATA(4,4′4″-Tris(N,Ndiphenylamino)triphenylamine), 2-TNATA(4,4′,4″-tris{N,-(2-naphthyl)-N-phenylamino}-triphenylamine), PEDOT/PSS(Poly(3,4-ethylenedioxythiophene)/Poly(4-styrenesulfonate)), PANI/DBSA(Polyaniline/Dodecylbenzenesulfonic acid), PANI/CSA(Polyaniline/Camphor sulfonicacid), PANI/PSS(Polyaniline/Poly(4-styrenesulfonate)), NPD(N,N′-di(naphthalene-1-yl)-N,N′-diphenylbenzidine), polyether ketone (TPAPEK) containing triphenylamine, 4-Isopropyl-4′-methyldiphenyliodonium[Tetrakis(pentafluorophenyl)borate], and HAT-CN(dipyrazino[2,3-f:2′,3′-h] quinoxaline-2,3,6,7,10,11-hexacarbonitrile)

The hole transport layer 153 may be disposed on the hole injection layer 151. The hole transport layer 153 may serve to facilitate transportation of holes from the pixel electrodes AE1, AE2 and AE3 to the light emitting layer 155. The hole transport layer 154 may include, for example, a carbazole-based derivative such as N-phenylcarbazole and polyvinyl carbazole, a fluorene-based derivative, TPD(N,N′-bis(3-methylphenyl)-N,N′-diphenyl-[1,1-biphenyl]-4,4′-diamine), a triphenylamine-based derivative such as TCTA(4,4′,4″-tris(N-carbazolyl)triphenylamine), NPD(N,N′-di(naphthalene-1-yl)-N,N′-diphenyl-benzidine), TAPC(4,4′-Cyclohexylidene bis[N,Nbis(4-methylphenyl)benzenamine]), HMTPD(4,4′-Bis[N,N′-(3-tolyl)amino]-3,3′-dimethylbiphenyl), and mCP(1,3-Bis(N-carbazolyl)benzene).

The light emitting layer 155 may be disposed on the hole transport layer 154. The light emitting layer 155 may include a host and a blue dopant. The host is not particularly limited as long as it is a commonly used material, but a condensed ring derivative such as anthracene or pyrene, a metal chelated oxynoid compound including tris(8-quinolinolato)aluminum, a bisstryl derivative such as a bisstryl anthracene derivative or a dystyrylbenzene derivative, a tetraphenylbutadiene derivative, a coumarin derivative, an oxadiazole derivative, perinone derivative, cyclopentadiene derivative, a pyrrolopyridine derivative, a pyrrolopyrrol derivative, a thiadiazolopyridine derivative, an oxadiazole derivative, a polymer-based polyphenylenevinylene derivative, a polyparaphenylene derivative, and a polythiophene derivative may be used as the host, and a substituent such as aryl, heteroaryl, arylvinyl, amino and cyano may be introduced into the derivative. For example, Alq3(tris(8-hydroxyquinolino)aluminum), CBP(4,4′-bis(N-carbazolyl)-1,1′-biphenyl), PVK(poly(n-vinylcabazole)), ADN(9,10-di(naphthalene-2-yl)anthracene), TCTA(4,4′,4″-Tris(carbazol-9-yl)-triphenylamine), TPBi(1,3,5-tris(N-phenylbenzimidazole-2-yl)benzene), TBADN(3-tert-butyl-9,10-di(naphth-2-yl)anthracene), DSA(distyryl arylene), CDBP(4,4′-bis(9-carbazolyl)-2,2″-dimethyl-biphenyl), or MADN(2-Methyl-9,10-bis(naphthalen-2-yl)anthracene) may be used.

The blue dopant is not particularly limited as long as it is a commonly used material, but may include, for example, a fluorescent material containing at least one of spiro-DPVBi, spiro-6P, distyryl-benzene (DSB), distyryl-arylene (DSA), Polyfluorene (PFO)-based polymer, poly(p-phenylene vinylene) (PPV)-based polymer, and a DABNA-based boron polycyclic compound. In another embodiment, the blue dopant may include a phosphorescent material containing an organometallic complex such as (4,6-F2ppy)2Ir(pic). A substituent such as aryl, heteroaryl, aryl vinyl, amino or cyano may be introduced into the compound exemplified as the blue dopant.

In an embodiment, the light emitting layer 155 may further include multiple quantum dots.

The quantum dot may be a granular material that emits light of a color while electrons are transited from a conduction band to a valence band. The quantum dot may have a specific band gap in accordance with its composition and size and thus may emit light having a wavelength after absorbing light. Examples of the semiconductor nano-crystal of the quantum dot may include a group-IV nano-crystal, a group II-VI compound nano-crystal, a group III-V compound nano-crystal, a group IV-VI nano-crystal or a combination thereof.

The group II-VI compound may be selected from a group consisting of: a two-element compound such as CdSe, CdTe, ZnS, ZnSe, ZnTe, ZnO, HgS, HgSe, HgTe, MgSe, MgS and a mixture thereof; a three-element compound such as InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof; and a four-element compound such as HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof.

The group III-V compound may be selected from a group consisting of: a two-element compound such as GaN, GaP, GaAs, GaSb, AlN, AlP, AlAs, AlSb, InN, InP, InAs, InSb and a mixture thereof; a three-element compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and a mixture thereof; and a four-element compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and a mixture thereof.

The group IV-VI compound may be selected from a group consisting of: a two-element compound such as SnS, SnSe, SnTe, PbS, PbSe, PbTe and a mixture thereof; a three-element compound such as SnSeS, SnSeTe, SnSTe, PbSeS, PbSeTe, PbSTe, SnPbS, SnPbSe, SnPbTe and a mixture thereof; and a four-element compound such as SnPbSSe, SnPbSeTe, SnPbSTe and a mixture thereof. The group IV element may be selected from a group consisting of Si, Ge and a mixture thereof. The group IV compound may be a two-element compound selected from a group consisting of SiC, SiGe and a mixture thereof.

In the specification, a two-element compound, a three-element compound, or a four-element compound may exist in particles at a uniform concentration, or may exist in a same particle by being divided into states having partially different concentration distributions. Also, a two-element compound, a three-element compound, or a four-element compounds may have a core/shell structure in which one quantum dot surrounds another quantum dot. An interface of the core and the shell may have a concentration gradient in which a concentration of an element existing in the shell decreases toward the center.

In an embodiment, the quantum dot may have a core-shell structure that includes a core having the aforementioned nano-crystal and a shell surrounding the core. The shell of the quantum dot may serve as a passivation layer for maintaining semiconductor characteristics by preventing chemical denaturation of the core from occurring, and/or may serve as a charging layer for giving electrophoresis characteristics to the quantum dot. The shell may be a single layer or multi-layer. An interface of the core and the shell may have a concentration gradient in which a concentration of an element existing in the shell decreases toward the center. Examples of the shell of the quantum dot may include a metal oxide, a non-metal oxide, a semiconductor compound, or a combination thereof.

For example, examples of a metal oxide or a non-metal oxide may include a two-element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO or a three-element compound such as MgAl₂O₄, CoFe₂O₄, NiFe₂O₄ and CoMn₂O₄, but the disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP and AlSb, but the disclosure is not limited thereto.

The quantum dot included in the light emitting layer 155 of the first light emitting structure EL1 may be different from the quantum dot of the light emitting layer 155 of the second light emitting structure EL2 and/or the quantum dot of the light emitting layer 155 of the third light emitting structure EL3. Some of the light emitting layer 155 of the first light emitting structure EL1, the light emitting layer 155 of the second light emitting structure EL2 and the light emitting layer 155 of the third light emitting structure EL3 may not include quantum dots. The light emitting layer 155 of the first light emitting structure EL1, the light emitting layer 155 of the second light emitting structure EL2 and the light emitting layer 155 of the third light emitting structure EL3 may include different quantum dots.

The electron transport layer 157 may be disposed on the light emitting layer 155. The electron transport layer 157 may serve to facilitate injection and transportation of electrons from the common electrode CE to the light emitting layer 155. The electron transport layer 157 may be formed of a composition for an electron transport layer, and the composition for an electron transport layer may include inorganic particles. The inorganic particles may include a metal oxide. For example, the electron transport layer 157 of the display device 1 may include ZnMgO or ZnO, but the disclosure is not limited thereto. In an embodiment, the electron transport layer 157 may include a two-element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, SnO₂, Ta₂O₃, ZrO₂, HfO₂ and Y₂O₃, or a three-element compound such as ZnMgO, MgAl₂O₄, CoFe₂O₄, NiFe₂O₄, CoMn₂O₄, BaTiO₃, BaZrO₃ and ZrSiO₄.

In an embodiment, the hole injection layer 151, the hole transport layer 153, the light emitting layer 155 and the electron transport layer 157, which constitute a light emitting structures EL1, EL2 and EL3, may be fabricated by an inkjet printing process.

The common electrode CE may be disposed on the light emitting structures EL1, EL2 and EL3. The common electrode CE may cover all of the light emitting structures EL1, EL2 and EL3 in each of the light emission areas EA1, EA2 and EA3 and the bank layer 160. The common electrode CE may include a transparent conductive material to transmit light generated from the light emitting structures EL1, EL2 and EL3. The common electrode CE may receive a common voltage or a low potential voltage. In case that the pixel electrodes AE1, AE2 and AE3 receive a voltage corresponding to the data voltage and the common electrode CE receives a low potential voltage, a potential difference may be formed between the pixel electrodes AE1, AE2 and AE3 and the common electrode CE, and light may be emitted from the light emitting structures EL1, EL2 and EL3.

The common electrode CE may include a material layer having a small work function, such as Li, Ca, LiF/Ca, LiF/Al, Al, Mg, Ag, Pt, Pd, Ni, Au Nd, Ir, Cr, BaF, Ba or a mixture thereof (e.g., a mixture of Ag and Mg). The common electrode CE may further include a transparent metal oxide layer disposed on a material layer having a small work function.

Although not shown, the common electrode CE may include a capping layer on the transparent conductive metal layer. The capping layer may serve to protect the transparent conductive metal. For example, the common electrode CE may be a single layer including a conductive metal, or may be a multi-layer layer including a conductive metal and the capping layer.

The display device 1 may include a second passivation layer 139 and a bank layer 160 disposed on the pixel electrodes AE1, AE2 and AE3. Referring to FIGS. 4 to 6, the bank layer 160 may include a first bank layer 161 extended in the first direction DR1, and a second bank layer 162 extended in the second direction DR2 and disposed on the first bank layer 161. The first bank layer 161 and the second bank layer 162 may cover edges of the pixel electrodes AE1, AE2 and AE3, and may expose at least a portion of the pixel electrodes AE1, AE2 and AE3.

The first bank layer 161 may include a stem portion 161_S extended in the first direction DR1 and a protrusion portion 161_P protruded from the stem portion 161_S in the second direction DR2. The first bank layer 161 may include multiple stem portions 161_S, and multiple protrusion portions 161_P may each be connected to a corresponding one of the stem portions 161_S.

The second bank layer 162 may include a stem portion 162_S extended in the second direction DR2 and a first protrusion portion 162_P1 protruded from the stem portion 162_S in the first direction DR1. The second bank layer 162 may include multiple stem portions 162_S, and multiple first protrusions 162_P1 may each be connected to a corresponding one of the stem portions 162_S.

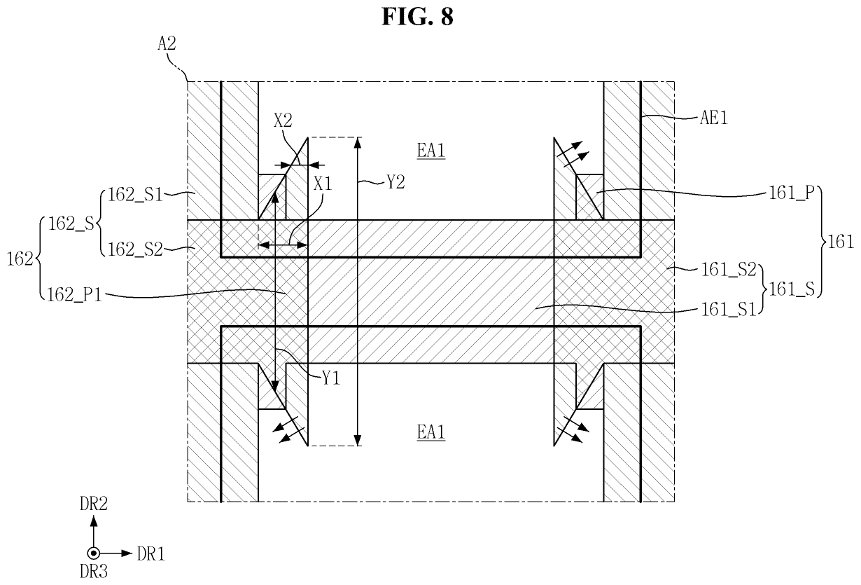

FIG. 8 is an enlarged plan view of area A2 of FIG. 4, and schematically illustrates the first bank layer 161 and the second bank layer 162 near a corner of the first light emission area EA1. The first bank layer 161 and the second bank layer 162 near the second light emission area EA2 and the third light emission area EA3 will be described based on the vicinity of the first light emission area EA1 by way of example.

The stem portion 161_S of the first bank layer 161 and the stem portion 162_S of the second bank layer 162 may intersect each other. The stem portion 161_S of the first bank layer 161 may include a crossing portion 161_S2 that overlaps the stem portion 162_S of the second bank layer 162 in a thickness direction DR3 and a first portion 161_S1 that does not overlap the stem portion 162_S of the second bank layer 162 in the thickness direction DR3. The stem portion 162_S of the second bank layer 162 may include a crossing portion 162_S2 that overlaps the stem portion 161_S of the first bank layer 161 in the thickness direction DR3 and a first portion 162_S1 that does not overlap the stem portion 161_S of the first bank layer 161 in the thickness direction DR3. The first portion 161_S1 of the first bank layer 161 may overlap the light emission areas EA1, EA2 and EA3 or the light emitting structures EL1, EL2 and EL3 in the second direction DR2. The first portion 162_S1 of the second bank layer 162 may overlap the light emission areas EA1, EA2 and EA3 or the light emitting structures EL1, EL2 and EL3 in the first direction DR1.

The protrusion portion 161_P of the first bank layer 161 may be protruded from the stem portion 161_S toward a side or another side in the second direction DR2. The protrusion portion 161_P of the first bank layer 161 may overlap the pixel electrodes EA1, EA2 and EA3 in the thickness direction DR3. The protrusion portion 161_P of the first bank layer 161 may be positioned at an end portion or a corner portion of the edges of the light emission areas EA1, EA2 and EA3. For example, the protrusion portion 161_P of the first bank layer 161 may be adjacent to the crossing portion 161_S2 between the stem portion 161_S of the first bank layer 161 and the stem portion 162_S of the second bank layer 162. The protrusion portion 161_P of the first bank layer 161 may overlap the light emission areas EA1, EA2 and EA3 or the light emitting structures EL1, EL2 and EL3 in the second direction DR2.

At least a portion of the protrusion portion 161_P of the first bank layer 161 may be exposed without being covered by the second bank layer 162. Due to the first protrusion portion 162_P1 of the second bank layer 162, inks of the light emitting structures EL1, EL2 and EL3 may not fill corner portions of the light emission areas EA1, EA2 and EA3, and a short between the pixel electrodes AE1, AE2 and AE3 and the common electrode CE may occur. In case that the protrusion portion 161_P of the first bank layer 161 is disposed at corners of the light emission areas EA1, EA2 and EA3, a short between electrodes may be prevented from occurring.

The protrusion portion 161_P of the first bank layer 161 illustrated in FIG. 8 has a rectangular shape, but the disclosure is not limited thereto. There is no limitation in the shape of the protrusion portion 161_P of the first bank layer 161 as far as the protrusion portion 161_P is exposed without being covered with the second bank layer 162 in the vicinity of the corner portions of the light emission areas EA1, EA2 and EA3 or the crossing portions of the first bank layer 161 and the second bank layer 162.

Protrusion portions 161_P of the first bank layers 161 may overlap each other in the first direction DR1 and the second direction DR2. Two of the protrusion portions 161_P protruded from one stem portion 161_S of the first bank layer 161 may overlap each other in the second direction DR2. One protrusion portion 161_P protruded from one stem portion 161_S of the first bank layer 161 may face one protrusion portion 161_P protruded from another stem portion 161_S in the second direction DR2.

The first protrusion portion 162_P1 of the second bank layer 162 may be protruded from the stem portion 162_S toward a side or another side in the first direction DR1. The first protrusion portion 162_P1 of the second bank layer 162 may be positioned at the end portion or corner portion of the edges of the light emission areas EA1, EA2 and EA3. For example, the first protrusion portion 162_P1 of the second bank layer 162 may be adjacent to the crossing portion 162_S2 between the stem portion 161_S of the first bank layer 161 and the stem portion 162_S of the second bank layer 162. The first protrusion portion 162_P1 of the second bank layer 162 may overlap the light emission areas EA1, EA2 and EA3 or the light emitting structures EL1, EL2 and EL3 in the first direction DR1.

First protrusions 162_P1 of the second bank layers 162 may overlap each other in the first direction DR1 and the second direction DR2. Two of the first protrusions 162_P1 protruded from one stem portion 162_S of the second bank layer 162 may overlap each other in the first direction DR1. One first protrusion 162_P1 protruded from one stem portion 162_S of the second bank layer 162 may face one first protrusion 162_P1 protruded from another stem portion 162_S in the first direction DR1.

The first protrusion portion 162_P1 of the second bank layer 162 may have a shape so as to apply a force to the ink of the light emitting structures EL1, EL2 and EL3 toward the edges of the light emission areas EA1, EA2 and EA3 in the first direction DR1 and apply a force to the ink toward the center of the light emission areas EA1, EA2 and EA3 in the second direction DR2. In FIG. 8, the direction in which the first protrusion portion 162_P1 of the second bank layer 162 exerts a force is indicated by a unidirectional arrow. In case that the force toward the edges of the light emission areas EA1, EA2 and EA3 in the first direction DR1 and the force toward the center of the light emission areas EA1, EA2 and EA3 in the second direction DR2 are combined with each other, the direction of the force shown in FIG. 8 may be obtained. Particles overflowing with inks from other light emission areas may be prevented from being diffused in the second direction DR2.

A length of the first protrusion portion 162_P1 of the second bank layer 162 in the second direction DR2 may be increased as it becomes far away from the stem portion 162_S. The first protrusion portion 162_P1 of the second bank layer 162 may include a first area adjacent to the stem portion 162_S and a second area adjacent to the light emission areas EA1, EA2 and EA3. The second area of the first protrusion portion 162_P1 of the second bank layer 162 may be different from the first area, and may be farther from the stem portion 162_S and closer to the center of the light emission areas EA1, EA2 and EA3 in the first direction DR1 than the first area. The first area and the second area may be extended in the second direction DR2. A length Y1 of the first area in the second direction DR2 may be less than a length Y2 of the second area in the second direction DR2. The lengths of the first area and the second area in the second direction DR2 may be the longest in the corresponding area in the second direction DR2. The length Y1 of the first area in the second direction DR2 may be greater than or equal to a width (or a length in the second direction DR2) of the stem portion 161_S1 of the first bank layer 161. The length Y2 of the second area in the second direction DR2 may be greater than the width (or the length in the second direction DR2) of the stem portion 161_S1 of the first bank layer 161.

The first protrusion portion 162_P1 of the second bank layer 162 may include a third area positioned between the first area and the second area. The third area may be extended in the second direction DR2. A length of the third area in the second direction DR2 may be greater than the length Y1 of the first area in the second direction DR2 and may be smaller than the length Y2 of the second area in the second direction DR2.

The first protrusion portion 162_P1 of the second bank layer 162 may overlap the first bank layer 161 in the thickness direction DR3. At least a portion of the first protrusion portion 162_P1 of the second bank layer 162 may non-overlap the stem portion 161_S of the first bank layer 161 in the thickness direction DR3. The first protrusion portion 162_P1 of the second bank layer 162 may have an eleventh area adjacent to or overlap the stem portion 161_S of the first bank layer 161 and a twelfth area adjacent to the light emission areas EA1, EA2 and EA3. The twelfth area of the first protrusion portion 162_P1 of the second bank layer 162 may be different from the eleventh area, and may be farther from the stem portion 161_S of the first bank layer 161 in the second direction DR2 and closer to the center of the light emission areas EA1, EA2 and EA3 than the eleventh area. The eleventh area and the twelfth area may be extended in the first direction DR1. A length X1 of the eleventh area in the first direction DR1 may be greater than a length X2 of the twelfth area in the first direction DR1. The lengths of the eleventh and twelfth areas in the first direction DR1 may be the longest in the corresponding area in the first direction DR1. In the first protrusion portion 162_P1 of the second bank layer 162, each of the eleventh and twelfth areas may overlap the first area or/and the second area.

The first protrusion portion 162_P1 of the second bank layer 162 may include a thirteenth area positioned between the eleventh area and the twelfth area. The thirteenth area may be extended in the first direction DR1. A length of the thirteenth area in the first direction DR1 may be smaller than a length X1 of the eleventh area in the first direction DR1, and may be greater than the length X2 of the twelfth area in the first direction DR1.

A portion of the light emitting structures EL1, EL2 and EL3 may be disposed between the first protrusion portion 162_P1 and the stem portion 162_S of the second bank layer 162. A length of the light emitting structures EL1, EL2 and EL3 disposed in a space between the first protrusion portion 162_P1 and the stem portion 162_S of the second bank layer 162 in the first direction DR1 may be reduced toward the edges of the light emission areas EA1, EA2 and EA3. For example, the light emitting structures EL1, EL2 and EL3 disposed between the stem portion 162_S of the second bank layer 162 and the first protrusion portion 162_P1 of the second bank layer 162 may include a 21st area adjacent to the crossing portions 161_S2 and 162_S2 of the first bank layer 161 and the second bank layer 162, and a 22nd area farther from the crossing portions 161_S2 and 162_S2 of the first bank layer 162 and the second bank layer 162 in the second direction DR2 than the 21st area. A length of the 21st area in the first direction DR1 may be smaller than a length of the 22nd area in the first direction DR1.

The light emitting structures EL1, EL2 and EL3 may fully or partially fill the space between the first protrusion portion 162_P1 and the stem portion 162_S of the second bank layer 162. In case that the ink forming the light emitting structures EL1, EL2 and EL3 does not completely fill the space between the first protrusion portion 162_P1 and the stem portion 162_S of the second bank layer 162, a short may be avoided by the first bank layer 161.

A shape of the first protrusion portion 162_P1 of the second bank layer 162 illustrated in FIG. 8 is a reverse-taper. The length of the first protrusion portion 162_P1 of the second bank layer 162 in the second direction DR2 may be gradually increased as it becomes far from the stem portion 162_S. A first protrusion portion 162_P1 may have a shape protruded toward two light emission areas EA1, EA2 and EA3. For example, a first protrusion portion 162_P1 may overlap two adjacent pixel electrodes AE1, AE2 and AE3 in the thickness direction DR3.

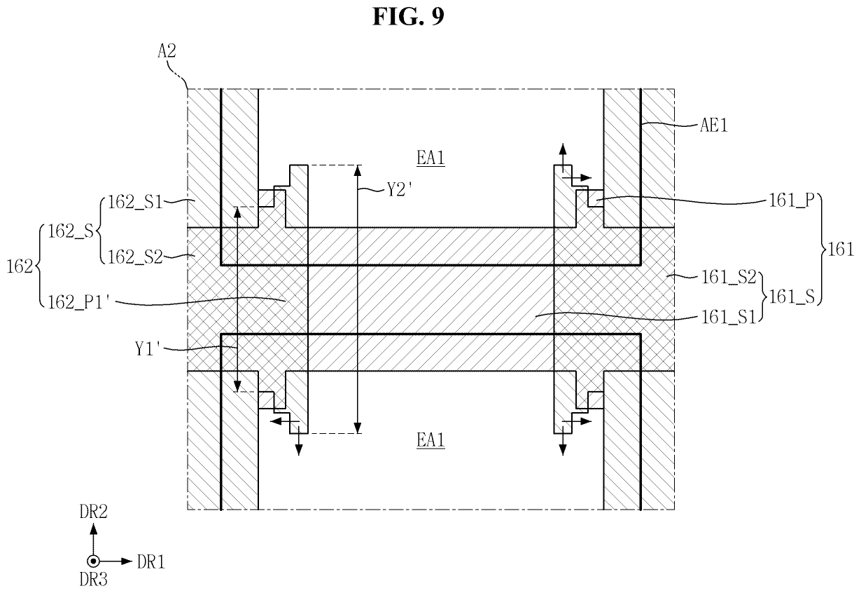

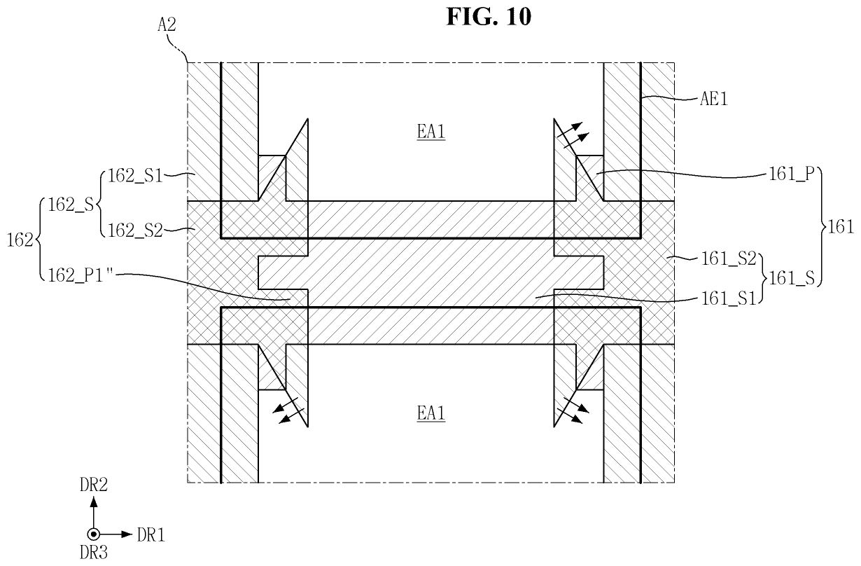

FIGS. 9 and 10 are enlarged plan views of the display device 1 according to an embodiment, respectively, and schematically illustrate shapes of the first protrusion portion 162_P1 of the second bank layer 162 according to an embodiment.

A shape of a first protrusion portion 162_P1′ of the second bank layer 162 in the embodiment of FIG. 9 may have steps. The first protrusion portion 162_P1′ of the second bank layer 162 may also apply a force toward the edges of the light emission areas EA1, EA2 and EA3 in the first direction DR1, and may apply a force toward the center of the light emission areas EA1, EA2 and EA3 in the second direction DR2 (refer to unidirectional arrows). The first protrusion portion 162_P1′ of the second bank layer 162 may have a short length Y1′ in the second direction DR2 in the first area adjacent to the stem portion 162_S and a long length Y2′ in the second direction DR2 in the second area adjacent to the center of the light emission areas EA1, EA2 and EA3.

A first protrusion portion 162_P1″ of the second bank layer 162 in the embodiment of FIG. 10 may be different from the embodiment of FIG. 8 at least in that a first protrusion portion 162_P1″ overlaps a pixel electrode AE1, AE2 or AE3 in the thickness direction DR3. A size of a first protrusion portion 162_P1″ may be relatively small, and the number of the first protrusion portions 162_P1″ may be increased. Two first protrusion portions 162_P1″ may be spaced apart from each other, and the first bank layer 161 may be exposed in a gap space between the first protrusion portions 162_P1″. The second bank layer 162 may have a groove shape on the stem portion 161_S of the first bank layer 161.

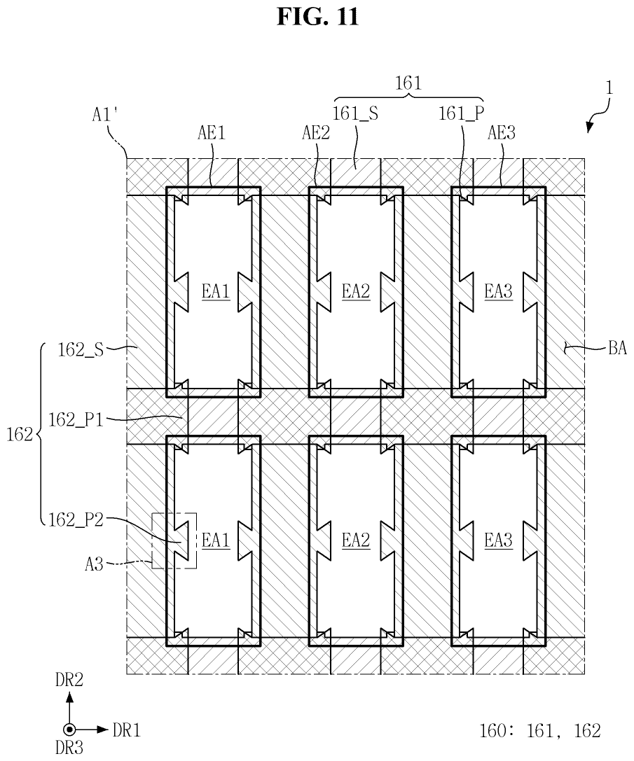

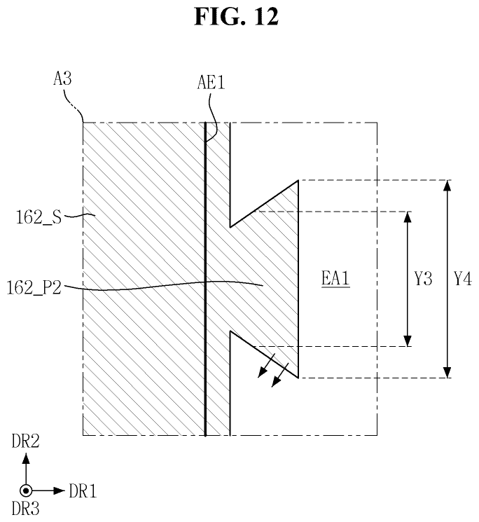

FIG. 11 is a plan view illustrating an arrangement of light emission areas EA1, EA2 and EA3 and a non-light emission area BA of the display device 1 according to an embodiment. FIG. 12 is an enlarged plan view of area A3 of FIG. 11.

In an embodiment, the second bank layer 162 may further include a second protrusion portion 162_P2 in a portion of the light emission area EA1 that is not a corner portion. The second protrusion portion 162_P2 of the second bank layer 162 may be protruded from the first portion 162_S2 of the stem portion 162_S of the second bank layer 162 toward a side or another side in the first direction DR1. In case that the light emission areas EA1, EA2 and EA3 have a length of a long side in the second direction DR2, in addition to the crossing portions of the first bank layer 161 and the second bank layer 162, the second protrusion portion 162_P2 may be provided at or near the center of the light emission areas EA1, EA2 and EA3 in the second direction DR2, thereby preventing particles of ink from being diffused in the second direction DR2.

At least a portion of the first protrusion portion 162_P1 of the second bank layer 162 may not overlap the pixel electrodes AE1, AE2 and AE3 in the thickness direction DR3, and the entire second protrusion portion 162_P2 may overlap the pixel electrodes AE1, AE2 and AE3 in the thickness direction DR3. The first protrusion portion 162_P1 and the second protrusion portion 162_P2 of the second bank layer 162 may have a same shape or size or different shapes or sizes in a plan view.

Second protrusions 162_P1 of the second bank layers 162 may overlap each other in the first direction DR1 and the second direction DR2. Two of the second protrusions 162_P1 protruded from one stem portion 162_S of the second bank layer 162 may overlap each other in the first direction DR1. One second protrusion 162_P1 protruded from one stem portion 162_S of the second bank layer 162 may face one second protrusion 162_P2 protruded from another stem portion 162_S in the first direction DR1.

The second protrusion portion 162_P2 of the second bank layer 162 may have a shape so as to apply a force to the ink of the light emitting structures EL1, EL2 and EL3 toward the edges of the light emission areas EA1, EA2 and EA3 in the first direction DR1 and apply a force to the ink toward ends of the light emission areas EA1, EA2 and EA3 in the second direction DR2.

A length of the second protrusion portion 162_P2 of the second bank layer 162 in the second direction DR2 may be increased as it becomes far away from the stem portion 162_S. The second protrusion portion 162_P2 of the second bank layer 162 may include a first area adjacent to the stem portion 162_S and a second area adjacent to the light emission areas EA1, EA2 and EA3. The second area of the second protrusion portion 162_P2 of the second bank layer 162 may be different from the first area, and may be farther from the stem portion 162_S and closer to the center of the light emission areas EA1, EA2 and EA3 in the first direction DR1 than the first area. The first area and the second area may be extended in the second direction DR2. A length Y3 of the first area in the second direction DR2 may be less than a length Y4 of the second area in the second direction DR2. The second protrusion portion 162_P2 of the second bank layer 162 may include a third area positioned between the first area and the second area. The third area may be extended in the second direction DR2. A length of the third area in the second direction DR2 may be greater than the length Y3 of the first area in the second direction DR2, and may be smaller than the length Y4 of the second area in the second direction DR2.

A shape of the second protrusion portion 162_P2 of the second bank layer 162 of the embodiment in FIG. 12 may be a reverse-taper. The length of the second protrusion portion 162_P2 of the second bank layer 162 in the second direction DR2 may be gradually increased as it becomes far from the stem portion 162_S.

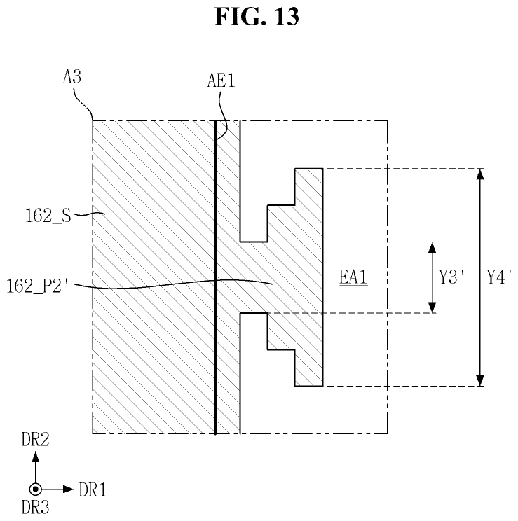

FIG. 13 is an enlarged plan view of the display device 1 according to an embodiment, and schematically illustrates another shape of the second protrusion portion 162_P2 of the second bank layer 162.

A shape of a second protrusion portion 162_P2′ of the second bank layer 162 of the embodiment in FIG. 13 may have steps. The first protrusion portion 162_P2′ of the second bank layer 162 may apply a force toward the edges of the light emission areas EA1, EA2 and EA3 in the first direction DR1, and may apply a force toward ends of the light emission areas EA1, EA2 and EA3 in the second direction DR2. The second protrusion portion 162_P2′ of the second bank layer 162 may have a short length Y3′ in the second direction DR2 in the first area adjacent to the stem portion 162_S and a long length Y4′ in the second direction DR2 in the second area adjacent to the center of the light emission areas EA1, EA2 and EA3.

Referring back to FIGS. 4 to 6, a thickness T1 of the second bank layer 162 may be greater than a thickness T2 of the first bank layer 161. Inks forming the light emitting structures EL1, EL2 and EL3 may overflow the first bank layer 161 having a small thickness T2, but may not overflow the second bank layer 162 having a greater thickness T1. As illustrated in FIG. 6 of a cross-sectional view taken along the line Q3-Q3′ in the second direction DR2, the first light emitting structure EL1 may be formed on the first bank layer 161, but as illustrated in FIG. 5 of a cross-sectional view taken along line Q2-Q2′ in the first direction DR1, the first light emitting structure EL1 may not be formed on the second bank layer 162. For example, the light emitting structures EL1, EL2 and EL3 may be extended in the second direction DR2 that is the extended direction of the second bank layer 162 having a greater thickness T1, but may be spaced apart from one another in the first direction DR1 that is the extended direction of the first bank layer 161 having a smaller thickness T2.

The bank layer 160 may include an organic material. For example, the bank layer 160 may include an acrylic resin (polyacrylates resin), an epoxy resin, a phenolic resin, a polyamides resin, a polyimides resin, an unsaturated polyesters resin, a poly phenylenethers resin, a polyphenylenesulfides resin, a benzocyclobutene (BCB), a hexamethyldisiloxane (HMDSO) or the like.

The first bank layer 161 may include a material of a lyophilic property. The second bank layer 162 may include a material of a liquid-repellent property. The liquid-repellent property may mean a property in which a solution is pushed out and the solution is not readily permeated. Also, the lyophilic property may mean a property of excellent affinity to the solution. For example, the solution may have a relatively small surface bonding force with a surface having the liquid-repellent property, and the solution disposed on a surface having the liquid-repellent property may have an increased surface tension. The solution may have a relatively large surface bonding force with a surface having the lyophilic property, and the solution disposed on a surface having the lyophilic property may have a reduced surface tension. The first bank layer 161 may include an organic material such as polyimide or hexamethyldisiloxane (HMDSO). The second bank layer 162 may include a fluorine-based material to increase a liquid-repellent property on the surface. The second bank layer 162 may include an organic material having an unsaturated bond and a fluoro group.

In an embodiment, the thin film encapsulation layer TFEL may be disposed on the common electrode CE. The thin film encapsulation layer TFEL may be commonly positioned in the first light emission area EA1, the second light emission area EA2, the third light emission area EA3 and the non-light emission area BA. In an embodiment, the thin film encapsulation layer TFEL may cover (e.g., directly cover) the common electrode CE.

In an embodiment, the thin film encapsulation layer TFEL may include a first encapsulation inorganic layer TFE1, an encapsulation organic layer TFE2 and a second encapsulation inorganic layer TFE3, which are sequentially stacked on the common electrode CE.

Each of the first encapsulation inorganic layer TFE1 and the second encapsulation inorganic layer TFE3 may include at least one of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and lithium fluoride. The encapsulation organic layer TFE2 may include an acrylic resin, a methacrylate resin, polyisoprene, a vinyl resin, an epoxy resin, a urethane resin, a cellulose resin, a perylene resin, or the like.

However, the structure of the thin film encapsulation layer TFEL is not limited to the above-described embodiments, and various modifications may be made in the stacked structure of the thin film encapsulation layer TFEL.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a pixel electrode disposed on a substrate;
a first bank layer covering an edge of the pixel electrode and including a stem portion extending in a first direction and a protrusion portion protruded from the stem portion in a second direction intersecting the first direction; and
a second bank layer disposed on the edge of the pixel electrode and a portion of the first bank layer and including a stem portion extending in the second direction and a first protrusion portion protruded from the stem portion in the first direction, wherein
the stem portion of the first bank layer and the stem portion of the second bank layer include a cross portion where the stem portion of the first bank layer and the stem portion of the second bank layer cross each other,
the protrusion portion of the first bank layer is adjacent to the crossing portion of the stem portion of the first bank layer, and
the first protrusion portion of the second bank layer is adjacent to the crossing portion of the stem portion of the second bank layer.

2. The display device of claim 1, wherein at least a portion of the protrusion portion of the first bank layer and at least a portion of the first protrusion portion of the second bank layer overlap the pixel electrode in a thickness direction of the substrate.

3. The display device of claim 1, wherein at least a portion of the protrusion portion of the first bank layer is exposed without being covered by the second bank layer.

4. The display device of claim 1, wherein
the first protrusion of the second bank layer includes a first area adjacent to the stem portion of the second bank layer and a second area farther from the stem portion of the second bank layer in the first direction than the first area, and
a length of the first area in the second direction is smaller than a length of the second area in the second direction.

5. The display device of claim 4, wherein
the first protrusion portion of the second bank layer includes a third area disposed between the first area and the second area, and
a length of the third area in the second direction is greater than a length of the first area in the second direction.

6. The display device of claim 5, wherein the length of the third area in the second direction is smaller than the length of the second area in the second direction.

7. The display device of claim 1, wherein
the first protrusion portion of the second bank layer includes an eleventh area adjacent to the stem portion of the first bank layer and a twelfth area farther from the stem portion of the first bank layer in the second direction than the eleventh area, and
a length of the eleventh area in the first direction is greater than a length of the twelfth area in the first direction.

8. The display device of claim 1, wherein the first protrusion portion of the second bank layer overlaps the first bank layer in a thickness direction of the substrate.

9. The display device of claim 8, wherein the second bank layer further includes a second protrusion portion protruded from the stem portion in the first direction and not overlapping the first bank layer in the thickness direction.

10. The display device of claim 9, wherein the second protrusion portion overlaps an entire area of the pixel electrode in the thickness direction.

11. The display device of claim 1, wherein a thickness of the second bank layer is greater than a thickness of the first bank layer.

12. The display device of claim 1, further comprising:
a light emitting structure disposed on the pixel electrode and the first bank layer.

13. The display device of claim 12, wherein the light emitting structure extends in the second direction.

14. The display device of claim 1, wherein
the first bank layer includes a lyophilic material, and
the second bank layer includes a liquid repellent material.

15. A display device comprising:
a pixel electrode disposed on a substrate;
a first bank layer covering an edge of the pixel electrode and extending in a first direction;
a second bank layer disposed on the edge of the pixel electrode and a portion of the first bank layer and including a stem portion extending in a second direction intersecting the first direction and a first protrusion portion protruded from the stem portion in the first direction; and
a light emitting structure disposed on the pixel electrode, wherein
the first protrusion portion of the second bank layer includes a first area adjacent to the stem portion of the second bank layer and a second area farther from the stem portion of the second bank layer in the first direction than the first area,
a length of the first area in the second direction is smaller than a length of the second area in the second direction, and
a portion of the light emitting structure is disposed between the stem portion of the second bank layer and the first protrusion portion of the second bank layer.

16. The display device of claim 15, wherein
the light emitting structure disposed between the stem portion of the second bank layer and the first protrusion portion of the second bank layer includes a 21st area adjacent to the first bank layer and a 22nd area farther from the first bank layer in the second direction than the 21st area, and
a length of the 21st area in the first direction is smaller than a length of the 22nd area in the first direction.

17. The display device of claim 15, wherein
the first bank layer includes a stem portion extending in the first direction and a protrusion portion protruded from the stem portion in the second direction, and
the protrusion portion of the first bank layer is disposed between the stem portion of the second bank layer and the first protrusion portion of the second bank layer.

18. The display device of claim 15, wherein
the first protrusion portion of the second bank layer includes a third area disposed between the first area and the second area, and
a length of the third area in the second direction is greater than a length of the first area in the second direction, and is smaller than a length of the second area in the second direction.

19. The display device of claim 15, wherein the first protrusion portion of the second bank layer has a reverse tapered shape or a stepped shape in a plan view.

20. The display device of claim 15, wherein the second bank layer further includes a second protrusion portion protruded from the stem portion in the first direction and not overlapping the first bank layer in a thickness direction of the substrate.
